(19) United States
(12) Patent Application Publication
(10) Pub. No.: US 2019/0320517 A1
(43) Pub. Date: Oct. 17, 2019

(54) LIGHT-EMITTING APPARATUS AND DISPLAY DEVICE

(71) Applicant: Sharp Kabushiki Kaisha, Sakai City, Osaka (JP)

(72) Inventors: Youhei NAKANISHI, Sakai City (JP); Masayuki KANEHIRO, Sakai City (JP)

(21) Appl. No.: 16/472,920

(22) PCT Filed: Sep. 29, 2017
(86) PCT No.: PCT/JP2017/035647

§ 371 Date: Jun. 24, 2019

(51) Int. Cl. H05B 33/14; G02B 5/20; G09F 9/30; H01L 27/32; H05B 33/22; H01L 33/08; H01L 33/06

(52) U.S. Cl. CPC H05B 33/145; G02B 5/20; G09F 9/30; G02F 2001/133614; H05B 33/22; H01L 33/08; H01L 33/06; H01L 27/32

(57) ABSTRACT

In a light-emitting apparatus, a blue light-emitting layer provided between the anode electrode and the cathode electrode includes blue QD phosphor particles emitting the first blue light by electro-luminescence. The light-emitting apparatus further includes a blue phosphor layer which receives the first blue light and emits a second blue light (a blue light with a longer peak wavelength than the first blue light).

### TECHNICAL FIELD

One aspect of the disclosure relates to a light-emitting apparatus including Quantum Dot (QD) phosphor particles.

### BACKGROUND ART

In recent years, for example, as a light source of a display device, a light-emitting apparatus including QD phosphor particles (also referred to as semiconductor nanoparticle phosphors) has been used. PTL 1 discloses an example of such a display device. The display device of PTL 1 is intended to improve light usage efficiency.

### CITATION LIST

### Patent Literature

PTL 1: JP 2016-142894 A

### SUMMARY

### Technical Problem

However, as will be described below, there is room for improvement in the configuration of the light-emitting apparatus for improving the color reproducibility of the display device. An object of one aspect of the disclosure is to provide a light-emitting apparatus capable of realizing a display device with excellent color reproducibility.

### Solution to Problem

In order to solve the above problem, a light-emitting apparatus according to one aspect of the disclosure is a light-emitting apparatus in which a first light-emitting layer is provided between a first electrode and a second electrode, wherein the first light-emitting layer includes a quantum dot phosphor particle configured to emit a first light by electro-luminescence and the light-emitting apparatus is further provided with a wavelength converting member configured to receive the first light and emit a second light that is a blue light with a longer peak wavelength than the first light.

### Advantageous Effects of Disclosure

According to a light-emitting apparatus of one aspect of the disclosure, it is possible to provide a light-emitting apparatus capable of realizing a display device with excellent color reproducibility.

### BRIEF DESCRIPTION OF DRAWINGS

FIG. 1 is a diagram illustrating a schematic configuration of a light-emitting apparatus according to a first embodiment.

FIG. 2 is a diagram illustrating a schematic configuration of a light-emitting apparatus according to a comparative example.

FIG. 3 is a diagram illustrating a schematic configuration of a light-emitting apparatus according to a second embodiment.

FIG. 4 is a diagram illustrating a schematic configuration of a light-emitting apparatus according to a third embodiment.

FIG. 5 is a diagram illustrating an example of a schematic configuration of a light-emitting apparatus according to a fourth embodiment.

FIG. 6 is a diagram illustrating another example of a schematic configuration of a light-emitting apparatus according to the fourth embodiment.

FIG. 7 is a diagram illustrating still another example of a schematic configuration of a light-emitting apparatus according to the fourth embodiment.

### DESCRIPTION OF EMBODIMENTS

### First Embodiment

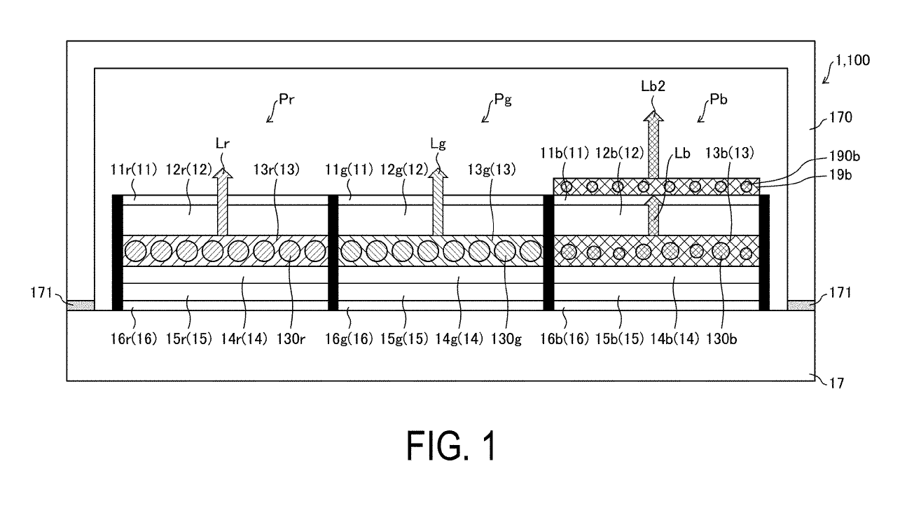

FIG. 1 illustrates a schematic configuration of a light-emitting apparatus 1 according to a first embodiment. A light-emitting apparatus 1 is used as a light source of a display device 100. That is, the display device 100 includes the light-emitting apparatus 1 as a light source. Of the members included in the light-emitting apparatus 1, the description of members not related to the first embodiment will be omitted. It may be understood that the members which omit these descriptions are similar to those known in the art. Further, it should be noted that each drawing schematically describes the shape, structure, and positional relationship of each member, and is not necessarily drawn to scale.

Configuration of Light-Emitting Apparatus 1

The light-emitting apparatus 1 is a light source that lights each pixel of the display device 100. In the first embodiment, the display device 100 expresses an image with a plurality of pixels of RGB (Red, Green, Blue). Hereinafter, the red pixel (R pixel) is referred to as Pr, the green pixel (G pixel) as Pg, and the blue pixel (B pixel) as Pb.

In the light-emitting apparatus 1, each of the red pixel Pr, the green pixel Pg, and the blue pixel Pb is partitioned by a light blocking member 99 (e.g. a black matrix). By dividing each pixel by the light blocking member 99, the outline of each pixel is emphasized. Therefore, the contrast of the image displayed on the display surface (not illustrated) of the display device 100 is improved.

The light-emitting apparatus 1 includes QD phosphor particles which emit light according to the combination of holes supplied from an anode electrode 16 (anode, second electrode) and electrons (free electrons) supplied from a cathode electrode 11 (cathode, first electrode). More specifically, the QD phosphor particles are contained in the light-emitting layer 13 (QD phosphor layer) provided between the anode electrode 16 and the cathode electrode 11. Hereinafter, a direction from the anode electrode 16 to the cathode electrode 11 is referred to as an upward direction. Also, the direction opposite to the upward direction is referred to as the downward direction.

The light-emitting apparatus 1 includes a cathode electrode 11, an Electron Transportation layer (ETL) 12, a light-emitting layer 13, a Hole Transportation layer (HTL) 14, a Hole Injection Layer (HIL) 15, an anode electrode 16, and a substrate 17 in this order in the downward direction.

In the present specification, the first electrode means the upper electrode among the two electrodes sandwiching the light-emitting layer 13. On the other hand, the second electrode means the lower electrode among the two electrodes sandwiching the light-emitting layer 13. In the first embodiment, the cathode electrode 11 is the first electrode and the anode electrode 16 is the second electrode.

The components between the cathode electrode 11 and the anode electrode 16 are supported by the substrate 17 provided below the anode electrode 16. As an example, when manufacturing the light-emitting apparatus 1, the anode electrode 16, the hole injection layer 15, the hole transportation layer 14, the light-emitting layer 13, the electron transportation layer 12, and the cathode electrode 11 are formed (film formation) on the substrate 17 in this order. In the light-emitting apparatus 1, the formation of the blue phosphor layer 19b described later is performed after the formation of the cathode electrode 11.

The substrate 17 may be a highly transparent substrate (e.g. glass substrate), or a substrate with a poorly transparent (e.g. flexible substrate). The light-emitting apparatus 1 further includes a sealing glass 170 that seals (protects) the components between the cathode electrode 11 and the anode electrode 16 and the blue phosphor layer 19b (described later). The sealing glass 170 is fixed to the substrate 17 by a sealing resin 171 (e.g. adhesive).

The components between the cathode electrode 11 and the anode electrode 16 may be individually provided for each of the red pixel Pr, the green pixel Pg, and the blue pixel Pb. For example, the cathode electrode 11 includes a cathode electrode 11r provided in the red pixel Pr, a cathode electrode 11g provided in the green pixel Pg, and a cathode electrode 11b provided in the blue pixel Pb.

In this way, in FIG. 1, the subscripts “r, g, b” are appended to distinguish the members corresponding to the red pixel Pr, the green pixel Pg, and the blue pixel Pb, as necessary. This is true for the electron transportation layer 12 (12r, 12g, 12b), the light-emitting layer 13 (13r, 13g, 13b), the hole transportation layer 14 (14r, 14g, 14b), the hole injection layer 15 (15r, 15g, 15b), and the anode electrode 16 (16r, 16g, 16b).

In particular, in the light-emitting layer 13 includes the red light-emitting layer 13r provided in the red pixel Pr, the green light-emitting layer 13g provided in the green pixel Pg, and the blue light-emitting layer 13b (first light-emitting layer) provided in the blue pixel Pb. The red light-emitting layer 13r includes red QD phosphor particles 130r (red quantum dot phosphor particles) that emit red light Lr. The green light-emitting layer 13g includes green QD phosphor particles 130g (green quantum dot phosphor particles) that emit green light Lg.

The blue light-emitting layer 13b includes blue QD phosphor particles 130b (blue quantum dot phosphor particles, quantum dot phosphor particles) that emit the first blue light Lb (first light). The blue light-emitting layer 13b is an example of the first light-emitting layer. The first blue light Lb is an example of light (first light) emitted from the first light-emitting layer.

In the first embodiment, the cathode electrode 11 (cathode) which is the first electrode is made of Indium Tin Oxide (ITO). That is, the cathode electrode 11 is a light-transmissive electrode (light extraction electrode) that transmits light (red light Lr, green light Lg, and first blue light Lb) emitted from the light-emitting layer 13. In this way, the light-emitting apparatus 1 can emit the light emitted from the light-emitting layer 13 in the upward direction. That is, the light-emitting apparatus 1 is configured as a top-emitting type light-emitting apparatus.

On the other hand, the anode electrode 16 (anode) which is the second electrode is made of Al (aluminum), for example. That is, the anode electrode 16 is a reflective electrode that reflects the light emitted from the light-emitting layer 13. According to this arrangement, among the light emitted from the light-emitting layer 13, the light going downward (not illustrated in FIG. 1) can be reflected by the anode electrode 16. As a result, the light reflected by the anode electrode 16 can be directed to the cathode electrode 11 (upward). Therefore, the usage efficiency of the light emitted from the light-emitting layer 13 can be improved.

The electron transportation layer 12 contains a material with excellent electron transport property. According to the electron transportation layer 12, the supply of electrons from the cathode electrode 11 to the light-emitting layer 13 can be promoted. The electron transportation layer 12 may also have a role of an electron injection layer (EIL). The hole injection layer 15 is a layer that promotes injection of electrons from the anode electrode 16 to the light-emitting layer 13. The hole injection layer 15 contains a material having excellent hole injection property. In addition, the hole transportation layer 14 contains a material with excellent hole transport property. The hole injection layer 15 and the hole transportation layer 14 enables to promote the supply of holes from the anode electrode 16 to the light-emitting layer 13.

By applying a forward voltage between the anode electrode 16 and the cathode electrode 11 (by setting the anode electrode 16 to a potential higher than that of the cathode electrode 11), (i) electrons can be supplied from the cathode electrode 11 to the light-emitting layer 13 and (ii) holes can be supplied from the anode electrode 16 to the light-emitting layer 13. As a result, in the light-emitting layer 13, light can be generated with a combination of holes and electrons. The application of the voltage may be controlled by a Thin Film Transistor (TFT) (not illustrated).

The material of the QD phosphor particles in the light-emitting layer 13 is a luminescent material (e.g. inorganic luminescent material) with a valence band level and a conduction band level. In the QD phosphor particles (luminescent material), excitons are generated in accordance with a combination of holes and electrons. QD phosphor particles emit light in accordance with deactivation of excitons. More specifically, the QD phosphor particle emits light when the exciton excited from the valence band level to the conduction band level transits to the valence band level.

In this way, the light-emitting layer 13 emits light by electro-luminescence (EL) (more specifically, injection type EL). The light-emitting layer 13 functions as a self light emitting type light emitting element. The light-emitting layer 13 does not require a known light emitting diode (LED) as a light source (e.g. backlight) of the display device 100. Therefore, a smaller display device 100 can be realized.

The light-emitting layer 13 (each of the red light-emitting layer 13r, the green light-emitting layer 13g and the blue light-emitting layer 13b) includes particles of a luminescent material that emits light in accordance with a combination of holes and electrons as QD phosphor particles (each of the red QD phosphor particles 130r and the green QD phosphor particles 130g, and the blue QD phosphor particles 130b).

As an example, the material of the QD phosphor particles may be at least one material (semiconductor material) selected from the group consisting of “InP, InN, InAs, InSb, InBi, ZnS, ZnSe, ZnO, In₂O₃, Ga₂O₃, ZrO₂, In₂S₃, Ga₂S₃, In₂Se₃, Ga₂Se₃, In₂Te₃, Ga₂Te₃, CdSe, CdTe, and CdS”. More specifically, nano-sized crystals (semiconductor crystals) of the above semiconductor material are used as the material of the QD phosphor particles.

For example, the red QD phosphor particles 130r, the green QD phosphor particles 130g, and the blue QD phosphor particles 130b may be CdSe/ZnS based core/shell type QD phosphor particles, respectively.

Alternatively, the red QD phosphor particles 130r and the green QD phosphor particles 130g may be InP/ZnS based QD phosphor particles, respectively. In this case, the blue QD phosphor particles 130b may be ZnSe/ZnS based QD phosphor particles.

In FIG. 1, spherical shape QD phosphor particles are exemplified. However, the shape of the QD phosphor particles is not limited to a spherical shape. For example, the shape of the QD phosphor particles may be rod shaped or wire shaped. Any shape known in the art may be applied to the shape of the QD phosphor particles. This also applies to the blue phosphor particles 190b described below.

Since QD phosphor particles have high luminous efficiency, they are suitable for improving luminous efficiency of the light-emitting apparatus 1 (display device 100). Also, by adjusting the size (e.g. grain diameter) of the QD phosphor particles, the energy band gap of the QD phosphor particles can be set. That is, adjusting the particle diameter of the QD phosphor particles allows the wavelength (more specifically, the wavelength spectrum) of the light emitted from the QD phosphor particles to be controlled.

Specifically, as the size of the QD phosphor particles is reduced, the peak wavelength (the wavelength at which the intensity peak in the wavelength spectrum can be obtained) of the light emitted from the QD phosphor particles can be made shorter. Therefore, as illustrated in FIG. 1, in the light-emitting layer 13, the size of the blue QD phosphor particles 130b tends to be smaller than the sizes of the red QD phosphor particles 130r and the green QD phosphor particles 130g.

The light-emitting apparatus 1 further includes a blue phosphor layer 19b (wavelength converting member). The blue phosphor layer 19b includes blue phosphor particles 190b that emit second blue light Lb2 (second light, fluoresce) when excited by the first blue light Lb (first light, excitation light). The second blue light Lb2 is blue light with a longer peak wavelength than the first blue light Lb.

As an example, the first blue light Lb has a peak wavelength in the vicinity of a wavelength of 440 nm. In contrast, the second blue light Lb2 has a peak wavelength in the vicinity of a wavelength of 460 nm. It is preferable to select a peak wavelength of the second blue light Lb2 which has a high color rendering property of blue. The peak wavelength of 460 nm is an example of a peak wavelength with high color rendering property of blue color.

In this way, the blue phosphor layer 19b receives the first blue light Lb (blue light of short wavelength) and converts the first blue light Lb into the second blue light Lb2 (blue light of long wavelength). For this reason, the blue phosphor layer 19b is also called a wavelength converting member. In this way, the blue phosphor layer 19b emits light by photo-luminescence (PL). The blue phosphor layer 19b functions as a light receiving type light emitting element.

The blue phosphor layer 19b may be disposed to cover the blue light-emitting layer 13b (to maximally overlap the blue light-emitting layer 13b) when viewed from the upward direction (direction normal to the light-transmissive electrode). In the example of FIG. 1, the blue phosphor layer 19b is disposed on the upper face of the cathode electrode 11b (a light-transmissive electrode corresponding to the blue phosphor layer 19b). According to this arrangement, it is possible to effectively receive (absorb) the first blue light Lb (excitation light) into the blue phosphor layer 19b. Accordingly, a sufficient amount of the second blue light Lb2 (fluoresce) can be generated in the blue phosphor layer 19b.

In the example of FIG. 1, the blue phosphor layer 19b is disposed such that the circumferential end of the blue phosphor layer 19b coincides with (aligned with) the circumferential end of the blue light-emitting layer 13b when viewed from above. According to this arrangement, since the size in the width direction of the blue phosphor layer 19b can be reduced, the manufacturing cost of the blue phosphor layer 19b can be lowered.

In addition, in the example of FIG. 1, the blue phosphor layer 19b is not disposed on the upper face of the cathode electrode 11r, 11g (light-transmissive electrode corresponding to the red light-emitting layer 13r, the green light-emitting layer 13g). That is, the blue phosphor layer 19b is arranged not to cover the red light-emitting layer 13r and the green light-emitting layer 13g when viewed from the normal direction of the light-transmissive electrode. According to this arrangement, the usage efficiency of the red light Lr and the green light Lg can be improved.

Any material may be selected as the material of the blue phosphor particles 190b as long as it can emit the second blue light Lb2 by PL. As an example, the material of the blue phosphor particles 190b may be aluminum oxynitride (AlON) or BaMgAl₁₀O₁₇: Eu²⁺ (BAM). As the blue phosphor particles 190b, any blue phosphor particles may be used as long as they are non QD phosphor particles.

According to the configuration of the light-emitting apparatus 1, (i) the red light Lr emitted from the red light-emitting layer 13r, (ii) the green light Lg emitted from the green light-emitting layer 13g, and (iii) the second blue light Lb2 (blue light obtained by converting the first blue light Lb emitted from the blue light-emitting layer 13b) emitted from the blue phosphor layer 19b, can be emitted upward as illumination light.

That is, the light-emitting apparatus 1 can emit the second blue light Lb2 (blue light generated by PL) as the blue component of the illumination light instead of the first blue light Lb (blue light generated by EL). The advantages of this configuration will be described later.

### COMPARATIVE EXAMPLE

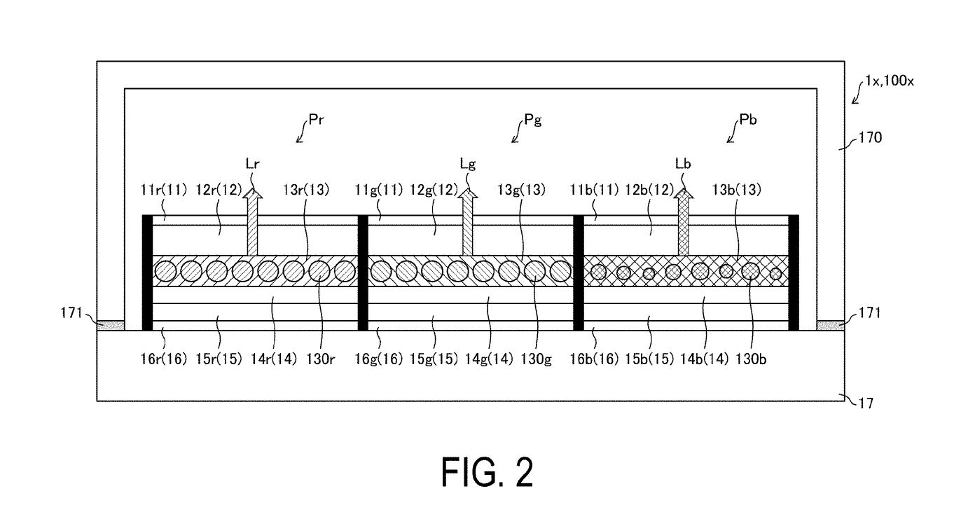

FIG. 2 illustrates a schematic configuration of a light-emitting apparatus 1x as a comparative example. The light-emitting apparatus 1x has a configuration in which the blue phosphor layer 19b is removed from the light-emitting apparatus 1. A display device including the light-emitting apparatus 1x is referred to as a display device 100x. In the light-emitting apparatus 1x, the first blue light Lb is emitted as a blue component of the illumination light.

As described above, the red QD phosphor particle 130r and the green QD phosphor particle 130g emit red light Lr and green light Lg (light with a peak wavelength longer than that of the first blue light Lb), respectively. Therefore, each of the red QD phosphor particles 130r and the green QD phosphor particles 130g is formed to be larger in size than the blue QD phosphor particles 130b.

Accordingly, it is easy to form the red QD phosphor particles 130r such that the sizes of the plurality of red QD phosphor particles 130r are uniform between the red QD phosphor particles 130r. Likewise, it is easy to form the green QD phosphor particles 130g so that the sizes of the plurality of green QD phosphor particles 130g are uniform between the green QD phosphor particles 130g. Therefore, for (i) the red light Lr emitted from each of the plurality of red QD phosphor particles 130r and (ii) the green light Lg emitted from each of the plurality of green QD phosphor particles 130g, it is easy to reduce variations in wavelength spectrum.

In contrast, the blue QD phosphor particles 130b emit the first blue light Lb (light with a peak wavelength shorter than the red light Lr and the green light Lg). Consequently, it is necessary for the blue QD phosphor particles 130b to be formed smaller than the red QD phosphor particles 130r and the green QD phosphor particles 130g.

Based on the above points, the inventors (hereinafter, the inventors) of the present application newly found an issue (problem) that “Different from the red QD phosphor particles 130r and the green QD phosphor particles 130g, the blue QD phosphor particles 130b are difficult to be formed such that the size between the blue QD phosphor particles 130b becomes uniform”.

Further, as described below, QD phosphor particles that emit light by EL have less degree of freedom in selection of materials than QD phosphor particles that emit light by EL. From this point of view, the inventors have newly found an issue that “it is particularly difficult to ensure the uniformity of size among the plurality of blue QD phosphor particles 130b that emit light by PL”.

Further, the inventors of the disclosure newly found an issue of “As for materials of the blue QD phosphor particles 130b, there is no other choice but to select materials that greatly affect the wavelength spectrum of the first blue light Lb, depending on the size difference of the blue QD phosphor particles 130b, thus, for the first blue light Lb emitted from each of the plurality of blue QD phosphor particles 130b, even if the size difference of each of the blue QD phosphor particles 130b is minute, the variation of the wavelength spectrum becomes large, and as a result, in the blue pixel Pb, a problem of unevenness (color drift) of blue which is the luminescent color occurs”.

Based on this point, the inventors newly found a further issue of “color drift occurs on the display surface of the display device 100x”. In addition, the inventors have newly discovered a further issue as follows; “when a plurality of display devices 100x are manufactured, the display performance of blue may be different between the plurality of display devices 100x, in other words, the display performance tends to vary among the plurality of display devices 100x (among lots)”.

Based on the above points, the inventors of the disclosure newly found a further issue of “when the first blue light Lb (blue light generated by EL) is used as the blue component of the illumination light of the light-emitting apparatus 1x, the color reproducibility of the display device 100x may be lowered”.

### Effect of Light-Emitting Apparatus 1

The inventors conceived a light-emitting apparatus 1 as a specific configuration for solving the issue (problem) caused in the light-emitting apparatus 1x. According to the light-emitting apparatus 1, the first blue light Lb (first light) emitted from the blue light-emitting layer 13b (first layer) may be converted into the second blue light Lb2 (second light) by the blue phosphor layer 19b (wavelength converting member).

Since the second blue light Lb2 is blue light generated by PL, the variation of the wavelength spectrum can be made smaller than the first blue light Lb (blue light generated by EL). The reason is as follows.

Since the blue phosphor particles 190b are non QD phosphor particles, the selectivity of the material is higher than that of the QD phosphor particles (the blue QD phosphor particles 130b). Accordingly, it is possible to select a material in which variations in size of the blue phosphor particles 190b have less influence on the wavelength spectrum of the second blue light Lb2.

In addition, since the blue phosphor particles 190b emit light by PL, unlike the QD phosphor particles, the wavelength of the fluoresce (the second blue light Lb2) is not determined by the quantum effect depending on the particle size. Therefore, even if there is a variation in the size of the blue phosphor particles 190b, the second blue light Lb2 with small variations in the wavelength spectrum may be easily obtained.

As described above, according to the light-emitting apparatus 1, unlike the light-emitting apparatus 1x, the second blue light Lb2 (blue light with less variation in the wavelength spectrum than the first blue light Lb) can be used as the blue component of the illumination light. As a result, the blue color drift in the blue pixel Pb can be reduced compared with the case of the light-emitting apparatus 1x. In other words, it becomes possible to provide a display device 100 with better color reproducibility than the display device 100x.

Further, in the light-emitting apparatus 1, (i) a red light-emitting layer 13r which emits red light Lr with small variation in wavelength spectrum and (ii) a green light-emitting layer 13g which emits green light Lg with small variation in wavelength spectrum, are further provided. Consequently, the color rendering property of the illumination light can be improved. As a result, an RGB image with excellent color reproducibility can be expressed in the display device 100.

As described above, the inventors of the disclosure have newly conceived a technical concept that “the first light (e.g. the first blue light Lb, which is blue light with a large variation in the wavelength spectrum generated by EL) is utilized as an excitation light to generate the second light (e.g. the second blue light Lb2, which is blue light with a small variation in the wavelength spectrum generated by PL)”.

The peak wavelength of the first blue light Lb is preferably in the range of about 380 nm to 440 nm. Further, it is preferable that the peak wavelength of the second blue light Lb2 is in the range of about 450 nm to 480 nm.

The size of the blue QD phosphor particles 130b is not particularly limited, but the diameter of the blue QD phosphor particles 130b generally may be about 2 nm to 10 nm. The size of the blue phosphor particles 190b is also not particularly limited, but the diameter of the blue phosphor particles 190b generally may be in the order of μm order (micron order). As described above, the blue phosphor particles 190b are sufficiently larger in size than the blue QD phosphor particles 130b.

The thickness (film thickness) of the blue light-emitting layer 13b is not particularly limited, but the thickness of the blue light-emitting layer 13b is about several tens of nm (the thickness of the blue phosphor particles 190b for one layer or two layers).

Although the thickness of the blue phosphor layer 19b is also not particularly limited, the thickness of the blue phosphor layer 19b is generally in the order of μm order (e.g. about several μm to 100 μm). This is because the blue phosphor layer 19b has a thickness sufficient for wavelength conversion. Thus, the blue phosphor layer 19b is sufficiently thick compared with the blue light-emitting layer 13b.

### Modified Example

The first light (light emitted from the blue light-emitting layer 13b) is not necessarily limited to visible light (blue light with a peak wavelength shorter than that of the second blue light Lb2). The first light may be invisible light if it functions suitably as excitation light to excite the blue phosphor particles 190b.

For example, the first light may be near-ultraviolet light. That is, the QD phosphor particles contained in the first light-emitting layer may emit near-ultraviolet light as the first light. As an example, the first light Lb may have a peak wavelength in the vicinity of, for example, a wavelength of 405 nm.

When the first light is near-ultraviolet light (invisible light), the component derived from the second blue light Lb2 becomes more dominant for the blue component of the illumination light. Consequently, it is possible to more effectively reduce the color drift of blue in the blue pixel Pb.

### Second Embodiment

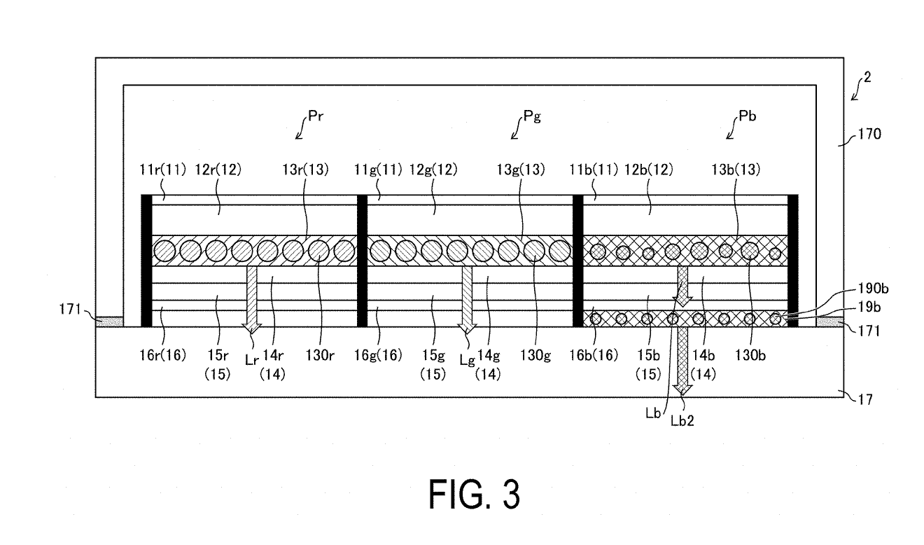

FIG. 3 illustrates a schematic configuration of the light-emitting apparatus 2 of a second embodiment. The light-emitting apparatus 2 is configured as a bottom-emitting type light-emitting apparatus. That is, the light-emitting apparatus 2 is configured to emit light (red light Lr, green light Lg, and first blue light Lb) emitted from the light-emitting layer 13 in a downward direction.

Specifically, by using a reflective electrode as the cathode electrode 11 (cathode) as the first electrode and a light-transmissive electrode as the anode electrode 16 (anode) as the second electrode respectively, the bottom-emitting type light-emitting apparatus 2 can be realized. In the light-emitting apparatus 2, the substrate 17 is a substrate (e.g. a glass substrate) with optical transparency.

In the light-emitting apparatus 2, the blue phosphor layer 19b may be disposed on the lower face of the anode electrode 16b (a light-transmissive electrode corresponding to the blue phosphor layer 19b). Also in this case, the blue phosphor layer 19b may be arranged to cover the blue light-emitting layer 13b (to maximally overlap the blue light-emitting layer 13b) when viewed from above. In the example of FIG. 3, the blue phosphor layer 19b is arranged such that the circumferential end of the blue phosphor layer 19b coincides with the circumferential end of the blue light-emitting layer 13b.

In addition, the blue phosphor layer 19b is not disposed on the lower face of the anode electrode 16r and 16g (light-transmissive electrodes corresponding to the red light-emitting layer 13r and the green light-emitting layer 13g). On the lower face of the anode electrode 16r and 16g, transparent resin is provided.

According to this arrangement, it is possible to effectively absorb the first blue light Lb into the blue phosphor layer 19b. Consequently, it is possible to emit the second blue light Lb2 going downward from the blue phosphor layer 19b.

As an example, when manufacturing the light-emitting apparatus 2, the blue phosphor layer 19b is first formed on the substrate 17. The formation of the anode electrode 16 is performed after the formation of the blue phosphor layer 19b. Thereafter, each member is formed in the same order as in the first embodiment.

Further, the blue phosphor layer 19b is not necessarily required to be disposed on the upper face of the cathode electrode 11b (in the case of the top-emitting type light-emitting apparatus 1) or the lower face of the anode electrode 16b (in the case of the bottom-emitting type light-emitting apparatus 2). That is, the blue phosphor layer 19b does not necessarily have to be provided in direct contact with the light-transmissive electrode.

For example, a light-transmissive member (e.g. a transparent adhesive layer) may be provided between the blue phosphor layer 19b and the light-transmissive electrode. In this case, the blue phosphor layer 19b is indirectly in contact with the light-transmissive electrode via the adhesive layer. The blue phosphor layer 19b may only have to be arranged over the cathode electrode 11b (in the case of the light-emitting apparatus 1) or under the anode electrode 16b (in the case of the light-emitting apparatus 2). In other words, it is sufficient that the blue phosphor layer 19b may be disposed on the side of the light-transmissive electrode.

### Third Embodiment

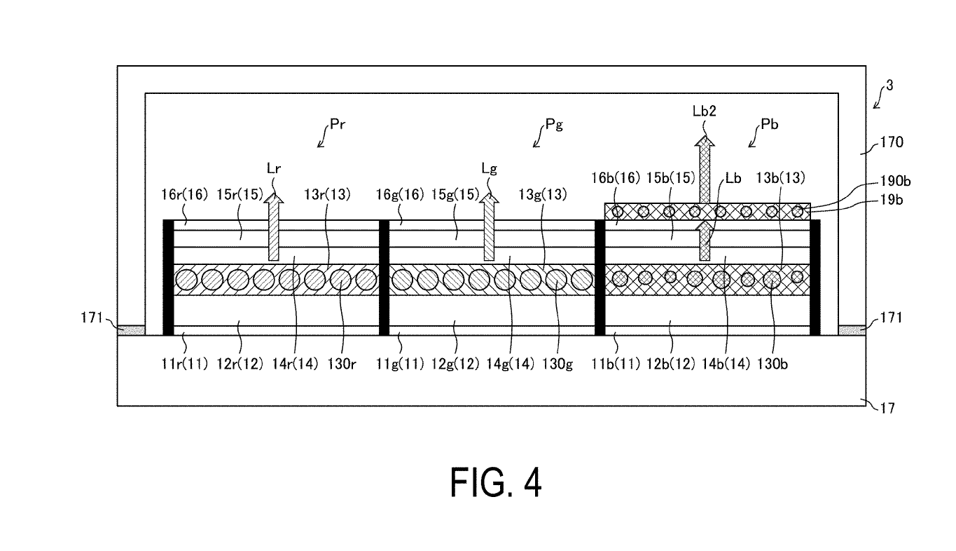

FIG. 4 illustrates a schematic configuration of the light-emitting apparatus 3 of a third embodiment. The light-emitting apparatus 3 is configured as an inverted top-emitting type light-emitting apparatus. That is, in the light-emitting apparatus 3, the cathode electrode 11, the electron transportation layer 12, the light-emitting layer 13, the hole transportation layer 14, the hole injection layer 15, and the anode electrode 16 are formed in this order on the substrate 17.

In the third embodiment, the anode electrode 16 (anode) is the first electrode and the cathode electrode 11 (cathode) is the second electrode. The anode electrode 16 is a light-transmissive electrode and the cathode electrode 11 is a reflective electrode. In the case of manufacturing the light-emitting apparatus 3, the formation of the blue phosphor layer 19b is performed after the anode electrode 16 is formed.

In the example of FIG. 4, the blue phosphor layer 19b is disposed on the upper face of the anode electrode 16b (a light-transmissive electrode corresponding to the blue phosphor layer 19b). Further, the blue phosphor layer 19b is not disposed on the upper face of the anode electrode 16r and 16g (light-transmissive electrodes corresponding to the red light-emitting layer 13r and the green light-emitting layer 13g).

### Fourth Embodiment

The light-emitting apparatus of each of the embodiments described above may be further provided with a color filter 195 that blocks at least a part of the first blue light Lb (excitation light not absorbed by the wavelength converting member) that has passed through the blue phosphor layer 19b. It is sufficient that the color filter 195 may be provided on the side of the light-transmissive electrode. More specifically, it is sufficient that the color filter 195 may be provided farther than the blue phosphor layer 19b when viewed from the blue light-emitting layer 13b. According to the color filter 195, since the component of the first blue light Lb can be excluded (filtered) from the illumination light, the blue color drift in the blue pixel Pb can be more effectively reduced.

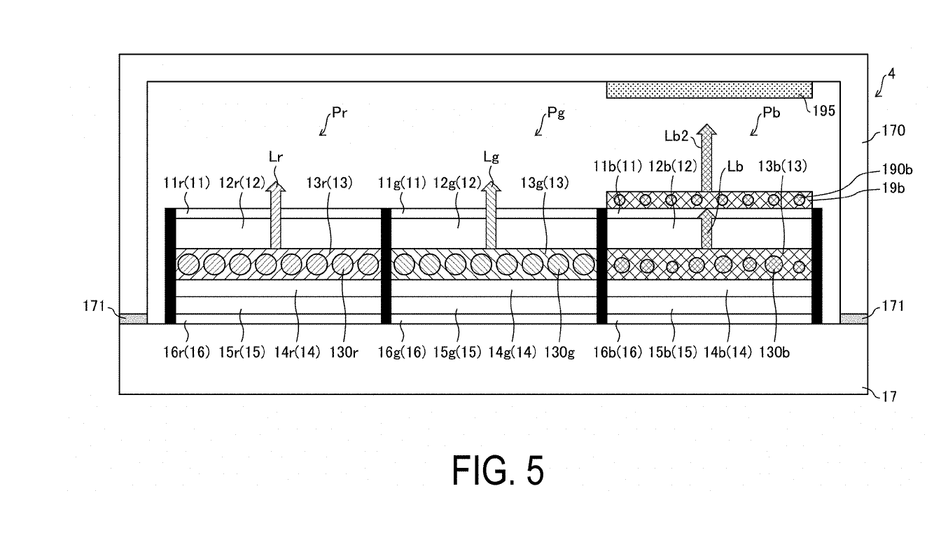

FIG. 5 to FIG. 7 illustrates a schematic configuration of the light-emitting apparatus of the fourth embodiment respectively. Hereinafter, the light-emitting apparatuses of FIG. 5 to FIG. 7 will be referred to as light-emitting apparatuses 4 to 6, respectively.

As illustrated in FIG. 5, the light-emitting apparatus 4 has a configuration in which a color filter 195 is added to a light-emitting apparatus 1 (top-emitting type light-emitting apparatus). In the light-emitting apparatus 4, the color filter 195 is provided on the lower face of the sealing glass 170.

The color filter 195 may be disposed to cover the blue phosphor layer 19b (to maximally overlap the blue phosphor layer 19b) when viewed from above. According to this arrangement, it is possible to more effectively filter the first blue light Lb that has passed through the blue phosphor layer 19b.

In the example of FIG. 5, the color filter 195 is disposed such that the circumferential end of the color filter 195 coincides with the circumferential end of the blue phosphor layer 19b. According to this arrangement, since the size in the width direction of the color filter 195 can be reduced, the manufacturing cost of the color filter 195 can be lowered.

In addition, the color filter 195 is arranged not to cover the red light-emitting layer 13r and the green light-emitting layer 13g when viewed from above. According to this arrangement, the usage efficiency of the red light Lr and the green light Lg can be improved.

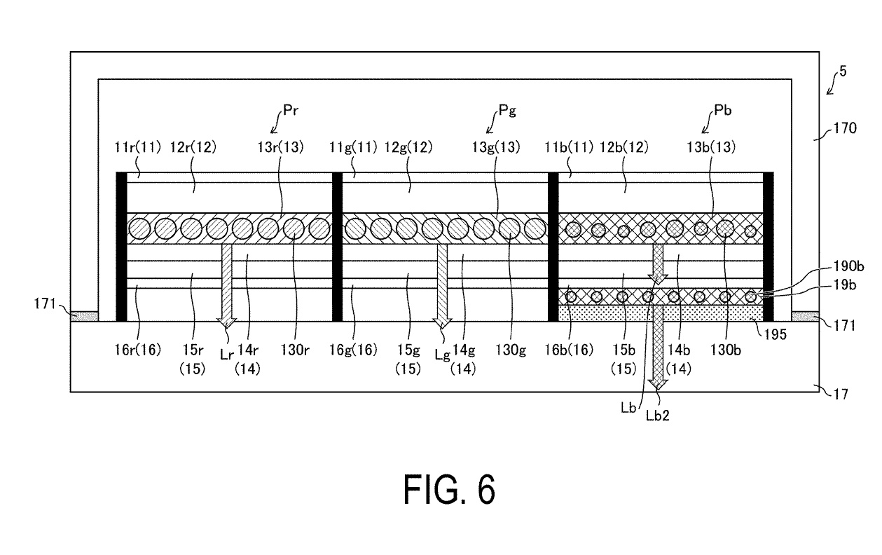

As illustrated in FIG. 6, the light-emitting apparatus 5 has a configuration in which a color filter 195 is added to a light-emitting apparatus 2 (a bottom-emitting type light-emitting apparatus). In the light-emitting apparatus 5, the color filter 195 is provided to cover the lower face of the blue phosphor layer 19b. In the case of manufacturing the light-emitting apparatus 5, the color filter 195 is first formed on the substrate 17. The formation of the blue phosphor layer 19b is performed after the formation of the color filter 195.

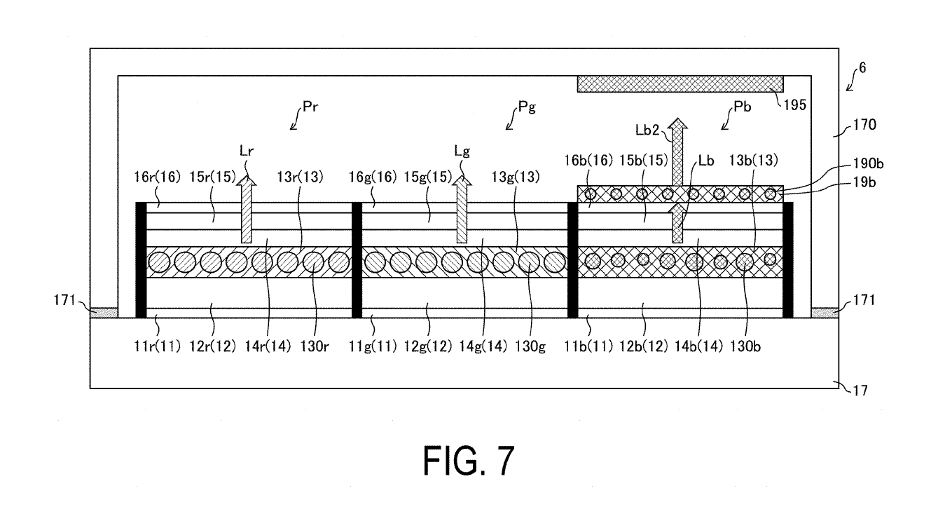

As illustrated in FIG. 7, the light-emitting apparatus 6 has a configuration in which a color filter 195 is added to a light-emitting apparatus 3 (an inverted top-emitting type light-emitting apparatus). The arrangement of the color filter 195 in the light-emitting apparatus 6 is the same as that of the light-emitting apparatus 4 in FIG. 5.

### Fifth Embodiment

According to the display device 100 (a display device including any one of the above-described light-emitting apparatuses 1 to 6 as a light source), it is possible to reduce the blue color drift in each of the plurality of blue pixels Pb. Paying attention to this point, the configuration of the display device 100 can also be expressed as follows.

The first blue light Lb has a larger variation in the wavelength spectrum than the red light Lr and the green light Lg. That is, in the display region of the display device 100, among the variations of the average value of the peak wavelengths in the respective wavelength spectrum of the red light Lr, the green light Lg, and the first blue light Lb (the first light), the variation of the first blue light Lb is largest.

When the first blue light Lb is irradiated on the blue phosphor layer 19b (wavelength converting member), the second blue light Lb2 (second light) is generated. The second blue light Lb2 is blue light with less variation in wavelength spectrum than the first blue light.

Therefore, the standard deviation of the average value of the peak wavelengths in the wavelength spectrum of the second blue light Lb2 is smaller than the standard deviation of the average value of the peak wavelengths in the wavelength spectrum of the first blue light Lb.

### Supplement

A light-emitting apparatus (1) according to a first aspect of the disclosure is a light-emitting apparatus provided with a first light-emitting layer (e.g. a blue light-emitting layer 13b) which is disposed between a first electrode (e.g. anode electrode 16) and a second electrode (e.g. cathode electrode 11), wherein the first light-emitting layer includes quantum dot phosphor particles emitting first light (e.g. first blue light Lb) by electro-luminescence, and the light-emitting apparatus further includes a wavelength converting member (blue phosphor layer 19b) to emit second light (second blue light Lb2), upon receiving the first light, with a longer peak wavelength than the first light.

According to the above configuration, the first light (e.g. light with a large variation in the wavelength spectrum generated by EL) is utilized as an excitation light to generate the second light (e.g. blue light with a small variation in the wavelength spectrum generated by PL). That is, in place of the first light (e.g. short wavelength blue light) emitted from the first light-emitting layer, the second light (e.g. long wavelength blue light) emitted from the wavelength converting member can be utilized as a blue component of the illumination light of the illumination device.

As a result, when the above light-emitting apparatus is used as the light source of the display device, the blue color drift in the display device can be reduced compared with the known device. Consequently, it is possible to provide a display device with better color reproducibility than the known display device.

In a light-emitting apparatus according to a second aspect of the disclosure, in the first aspect, one of the first electrode and the second electrode is a light-transmissive electrode, the wavelength converting member is disposed on the side of the light-transmissive electrode, and when viewed from a normal direction of the light-transmissive electrode, the wavelength converting member is preferably placed to cover the first light-emitting layer.

According to the above configuration, the wavelength converting member can effectively receive the first light. Therefore, it is possible to generate a sufficient amount of second light in the wavelength converting member.

In a light-emitting apparatus according to a third aspect of the disclosure, in the second aspect, when viewed from the normal direction of the light-transmissive electrode, the circumferential end of the wavelength converting member preferably coincides with the circumferential end of the first light-emitting layer.

According to the above configuration, the manufacturing cost of the wavelength converting member can be reduced.

In a light-emitting apparatus according to a fourth aspect of the disclosure, in any one of the first to third aspects, it is preferable that the first light is blue light or near-ultraviolet light with a peak wavelength shorter than that of the second light.

According to the above configuration, the first light can be suitably used as the excitation light. In particular, when the first light is near-ultraviolet light (invisible light), the color drift described above can be further reduced.

A light-emitting apparatus according to a fifth aspect of the disclosure, in any one of the first to fourth aspects, further includes: a green light-emitting layer (13g) provided between the first electrode and the second electrode; and a red light-emitting layer (13r) provided between the first electrode and the second electrode, and the green light-emitting layer preferably includes green quantum dot phosphor particles (green QD phosphor particles 130g) emitting green light (Lg) by electro-luminescence, and the red light-emitting layer preferably includes red quantum dot phosphor particles (red QD phosphor particles 130r) emitting red light (Lr) by electro-luminescence.

According to the above configuration, since the red component and the green component can be added to the illumination light, the color rendering property of the illumination light can be improved. In addition, since the wavelengths of the red light and the green light are longer than that of the first light (e.g. the blue light of the short wavelength), the variation of the wavelength spectrum may be smaller than that of the first light. As a result, an RGB image excellent in color reproducibility can be expressed on the display device.

In a light-emitting apparatus according to a sixth aspect of the disclosure, in the fifth aspect, one of the first electrode and the second electrode is a light-transmissive electrode, and the wavelength converting member is disposed on the side of the light-transmissive electrode, and when viewed from a normal direction of the light-transmissive electrode, the wavelength converting member is preferably disposed not to cover the green light-emitting layer and the red light-emitting layer.

According to the above configuration, the usage efficiency of the red light and the green light can be improved.

A light-emitting apparatus according to a seventh aspect of the disclosure is, in any one of the first to sixth aspects, is preferably further provided with a color filter (195) to block at least a part of the first light having passed through the wavelength converting member.

According to the above configuration, since the first light component can be excluded (filtered) from the illumination light, the color drift can be more effectively reduced.

In a light-emitting apparatus according to an eighth aspect of the disclosure, in the seventh aspect, one of the first electrode and the second electrode is a light-transmissive electrode, and the color filter is disposed on the side of the light-transmissive electrode, and when viewed from a normal direction of the light-transmissive electrode, the color filter is disposed to cover the wavelength converting member.

According to the above configuration, the first light can be more effectively filtered.

In a light-emitting apparatus according to the ninth aspect of the disclosure, in the seventh aspect, it is preferable that the circumferential end of the color filter coincides with the circumferential end of the wavelength converting member.

According to the above configuration, the manufacturing cost of the color filter can be reduced.

A light-emitting apparatus according to a tenth aspect of the disclosure, in the eighth and ninth aspect, further includes: a green light-emitting layer provided between the first electrode and the second electrode; and a red light-emitting layer provided between the first electrode and the second electrode. The green light-emitting layer includes green quantum dot phosphor particles to emit green light by electro-luminescence, the red light-emitting layer includes red quantum dot phosphor particles to emit red light by electro-luminescence, and it is preferable that the color filter is disposed not to cover the green light-emitting layer and the red light-emitting layer when viewed from a normal direction of the light-transmissive electrode.

According to the above configuration, the usage efficiency of the red light and the green light can be improved.

A display device (100) according to an eleventh aspect of the disclosure preferably includes a light-emitting apparatus according to any one of the first to tenth aspects.

In a display device according to a 12th aspect of the disclosure, in the eleventh aspect, the standard deviation of the average value of the peak wavelengths in the wavelength spectrum of the second light is smaller than the standard deviation of the average value of peak wavelengths in the wavelength spectrum of the first light.

Additional Items

One aspect of the disclosure is not limited to each of the embodiments stated above, and various modifications are possible within the scope indicated in the claims, and embodiments obtained by appropriately combining technical means stated in each of the different embodiments also fall within the technical scope of one aspect of the disclosure. Furthermore, by combining technical means disclosed in each of the embodiments, new technical features can be formed.

### REFERENCE SIGNS LIST

1, 2, 3, 4, 5, 6 Light-emitting apparatus
11, 11b Cathode electrode (first electrode, second electrode, light-transmissive electrode)
13b Blue light-emitting layer (first light-emitting layer)
13g Green light-emitting layer
13r Red light-emitting layer
16, 16b Anode electrode (second electrode, first electrode, light-transmissive electrode)
19b Blue phosphor layer (wavelength converting member)
100 Display device
130b Blue QD phosphor particle (Quantum Dot phosphor particle)
130g Green QD phosphor particle (green Quantum Dot phosphor particle)
130r Red QD phosphor particle (red Quantum Dot phosphor particle)
190b Blue phosphor particle
195 Color filter
Lb First blue light (first light, excitation light)
Lb2 Second blue light (second light, fluoresce)
Lg Green light
Lr Red light

1. A light-emitting apparatus provided with a first light-emitting layer between a first electrode and a second electrode,
wherein the first light-emitting layer includes quantum dot phosphor particles configured to emit first light by electro-luminescence,
the light-emitting apparatus further includes a wavelength converting member configured to emit second light which is blue light, upon receiving the first light, with a peak wavelength longer than that of the first light,
and further includes
a green light-emitting layer provided between the first electrode and the second electrode, and
a red light-emitting layer provided between the first electrode and the second electrode,
the green light-emitting layer includes green quantum dot phosphor particles configured to emit green light by electro-luminescence, and
the red light-emitting layer includes red quantum dot phosphor particles configured to emit red light by electro-luminescence.

2. The light-emitting apparatus according to claim 1,
wherein one of the first electrode and the second electrode is a light-transmissive electrode,
the wavelength converting member is disposed on a side of the light-transmissive electrode, and
when viewed from a normal direction of the light-transmissive electrode, the wavelength converting member is placed to cover the first light-emitting layer.

3. The light-emitting apparatus according to claim 2,
wherein when viewed from the normal direction of the light-transmissive electrode, a circumferential end of the wavelength converting member coincides with a circumferential end of the first light-emitting layer.

4. The light-emitting apparatus according to claim 1,
wherein the first light is blue light or near-ultraviolet light with a peak wavelength shorter than that of the second light.

5. (canceled)

6. The light-emitting apparatus according to claim 1,
wherein one of the first electrode and the second electrode is a light-transmissive electrode,
the wavelength converting member is disposed on a side of the light-transmissive electrode, and
when viewed from a normal direction of the light-transmissive electrode, the wavelength converting member is disposed not to cover the green light-emitting layer and the red light-emitting layer.

7. The light-emitting apparatus according to claim 1, further comprising:
a color filter configured to block at least a part of the first light having passed through the wavelength converting member.

8. The light-emitting apparatus according to claim 7,
wherein one of the first electrode and the second electrode is a light-transmissive electrode,
the color filter is disposed on a side of the light-transmissive electrode, and
when viewed from a normal direction of the light-transmissive electrode, the color filter is disposed to cover the wavelength converting member.

9. The light-emitting apparatus according to claim 8,
wherein when viewed from the normal direction of the light-transmissive electrode, a circumferential end of the color filter coincides with the circumferential end of the wavelength converting member.

10. The light-emitting apparatus according to claim 8, further comprising:
a green light-emitting layer provided between the first electrode and the second electrode; and
a red light-emitting layer provided between the first electrode and the second electrode,
wherein the green light-emitting layer includes green quantum dot phosphor particles configured to emit green light by electro-luminescence,
the red light-emitting layer includes red quantum dot phosphor particles configured to emit red light by electro-luminescence, and
the color filter is disposed not to cover the green light-emitting layer and the red light-emitting layer when viewed from the normal direction of the light-transmissive electrode.

11. A display device comprising the light-emitting apparatus according to claim 1.

12. The display device according to claim 11,
wherein a standard deviation of an average value of peak wavelengths in a wavelength spectrum of the second light is smaller than a standard deviation of an average value of peak wavelengths in a wavelength spectrum of the first light.

13. A light-emitting apparatus provided with a first light-emitting layer between a first electrode and a second electrode,
wherein the first light-emitting layer includes quantum dot phosphor particles configured to emit first light by electro-luminescence,
the light-emitting apparatus further includes a wavelength converting member configured to emit second light which is blue light, upon receiving the first light, with a peak wavelength longer than that of the first light, and
further includes a color filter configured to block at least a part of the first light having passed through the wavelength converting member,
one of the first electrode and the second electrode is a light-transmissive electrode,
the color filter is disposed on a side of the light-transmissive electrode,
when viewed from a normal direction of the light-transmissive electrode, the color filter is disposed to cover the wavelength converting member,
the light-emitting apparatus further includes
a green light-emitting layer provided between the first electrode and the second electrode, and
a red light-emitting layer provided between the first electrode and the second electrode,
the green light-emitting layer includes green quantum dot phosphor particles configured to emit green light by electro-luminescence,
the red light-emitting layer includes red quantum dot phosphor particles configured to emit red light by electro-luminescence, and
the color filter is disposed not to cover the green light-emitting layer and the red light-emitting layer when viewed from the normal direction of the light-transmissive electrode.

14. The light-emitting apparatus according to claim 13,
wherein one of the first electrode and the second electrode is a light-transmissive electrode,
the wavelength converting member is disposed on the side of the light-transmissive electrode, and
when viewed from the normal direction of the light-transmissive electrode, the wavelength converting member is placed to cover the first light-emitting layer.

15. The light-emitting apparatus according to claim 14,
wherein when viewed from the normal direction of the light-transmissive electrode, a circumferential end of the wavelength converting member coincides with a circumferential end of the first light-emitting layer.

16. The light-emitting apparatus according to claim 13,
wherein the first light is blue light or near-ultraviolet light with a peak wavelength shorter than that of the second light.

17. The light-emitting apparatus according to claim 13,
wherein when viewed from the normal direction of the light-transmissive electrode, a circumferential end of the color filter coincides with the circumferential end of the wavelength converting member.

18. A display device comprising the light-emitting apparatus according to claim 13.

19. The display device according to claim 18,
wherein a standard deviation of an average value of peak wavelengths in a wavelength spectrum of the second light is smaller than a standard deviation of an average value of peak wavelengths in a wavelength spectrum of the first light.
